(19) United States
(12) Patent Application Publication
(10) Pub. No.: US 2012/0267737 A1
(43) Pub. Date: Oct. 25, 2012

(54) SIDE SHIELDING CATHODE DESIGN FOR A RADIATION DETECTOR WITH IMPROVED EFFICIENCY

(75) Inventors: Henry Chen, Victoria (CA); Salah Awadalla, Victoria (CA); Pramodha Marthandam, Victoria (CA)

(73) Assignee: Redlen Technologies, Saanichton (CA)

(21) Appl. No.: 13/451,670

(22) Filed: Apr. 20, 2012

Related U.S. Application Data
(60) Provisional application No. 61/477,862, filed on Apr. 21, 2011.

(51) Int. Cl. H01L 31/08; H01L 31/18

(52) U.S. Cl. 257/429; 438/93; 257/E31.052

(57) ABSTRACT

A radiation detector includes a semiconductor substrate which contains front and rear major surfaces and at least one side surface, a guard ring and a plurality of anode electrode pixels located over the rear surface of the semiconductor substrate, where each anode electrode pixel is formed between adjacent pixel separation regions, a side insulating layer formed on the at least one side surface of the semiconductor substrate, a cathode electrode located over the front major surface of the semiconductor substrate, and an electrically conductive cathode extension formed over at least a portion of side insulating layer, where the cathode extension contacts an edge of the cathode electrode. Further embodiments include various methods of making such semiconductor radiation detector.

The present application claims benefit of priority of U.S. provisional application Ser. No. 61/477,862 filed on Apr. 21, 2012, which is incorporated herein by reference in its entirety.

### BACKGROUND

The general requirement for room temperature operation of a semiconducting material as a radiation detector or spectrometer (e.g., for a PET or CT scanner) is relatively large band gap energy such that thermal generation of charge carriers is kept to a minimum. Conversely, the requirement for high resolution is small band gap energy such that a large number of electron-hole pairs are created for an absorbed quantum of ionizing radiation. The material under consideration should also have a relatively high average atomic number if used in gamma ray spectroscopy to increase the gamma ray interaction probability. High charge carrier mobilities and long charge carrier lifetimes are also needed to ensure efficient charge carrier extraction and minimal effects from position-dependent charge collection. Detectors fabricated from Cadmium Zinc Telluride (CZT) meet these requirements and are used for gamma and X-ray detection. However, in addition to excellent bulk properties of the CZT single crystal, the fabrication process and structure to create electrodes on the detector is important for high performance of the detector device.

### SUMMARY

Various embodiments include a method of making a semiconductor radiation detector with an extended cathode including providing a semiconductor substrate comprising front and rear major surfaces and at least one side surface, forming a plurality of anode electrodes over the rear major surface of the substrate, forming a side insulating layer over the at least one side surface of the substrate, forming a cathode electrode over the front major surface of the substrate, forming a sacrificial layer over the cathode electrode, forming a conductive material layer over the sacrificial layer and over at least a portion of the side insulating layer; and lifting off the sacrificial layer to remove a first portion of the conductive material layer located over the cathode electrode while leaving a second portion of the conductive material layer over the side insulating layer, such that the second portion of the conductive material layer contacts an edge of the cathode electrode.

Further embodiments include a radiation detector which includes a semiconductor substrate which contains front and rear major surfaces and at least one side surface, a guard ring and a plurality of anode electrode pixels located over the rear surface of the semiconductor substrate, where each anode electrode pixel is formed between adjacent pixel separation regions, a side insulating layer formed on the at least one side surface of the semiconductor substrate, a cathode electrode located over the front major surface of the semiconductor substrate, and an electrically conductive cathode extension formed over at least a portion of side insulating layer, where the cathode extension contacts an edge of the cathode electrode.

Another embodiment includes radiation detector includes a semiconductor substrate which contains front and rear major surfaces and at least one side surface, a plurality of anode electrode pixels located over the rear surface of the semiconductor substrate, where each anode electrode pixel is formed between adjacent pixel separation regions, a side insulating layer formed on the at least one side surface of the semiconductor substrate, a cathode electrode located over the front major surface of the semiconductor substrate, and an electrically conductive cathode extension formed over at least a portion of side insulating layer, where the cathode extension contacts an edge of the cathode electrode, and where at least 85 percent of total pixels on the substrate have greater than 42 percent efficiency.

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIGS. 1A-F are schematic side cross sectional views of a method of making a detector at various stages of formation according to one embodiment.

FIG. 2 is a perspective view of a semiconductor substrate with anode electrode pixels.

FIG. 3 is a side cross sectional view of a semiconductor substrate with anode electrode pixels and a guard ring.

FIG. 4 is a perspective view of a semiconductor substrate with anode electrode pixels and a guard ring.

FIG. 5 is a side cross sectional view of an embodiment radiation detector at one stage of production.

FIG. 6 is a side cross sectional view of an embodiment radiation detector at another stage of production.

FIG. 7 is side cross sectional view of an embodiment radiation detector.

FIG. 8 is a table of experimental results showing the improved efficiency and sensitivity of embodiment radiation detectors.

FIG. 9 is a flow chart of a method for producing embodiment radiation detectors.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

The various embodiments provide radiation detectors with extended cathodes that provide greater efficiency and sensitivity than known detectors. Specifically, various embodiments may provide improved performance by peripheral anode electrodes in a pixel array. Embodiments may also include anodes formed by reverse lithography that provide decreased interpixel leakage currents and the attendant detrimental noise effects.

Radiation detectors may be configured in many ways. For example, embodiment detectors may include a cathode electrode and a plurality of anode electrodes located on opposite sides of a semiconductor plate or substrate. The cathode electrode may be positioned towards a radiation source. The plurality of anode electrodes may be arranged as an array of pixels including gaps between the pixels, termed an interpixel gap, interpixel region, or pixel separation region. Each anode electrode pixel may be held at an electric potential and thereby form one of a plurality of detector channels that may produce a detector output indicating the position at which radiation impacts the detector.

In various embodiments the semiconductor material may comprise cadmium zinc telluride (CdZnTe or CZT) or CdTe. Alternate embodiments may include other types of semiconductor materials such as lead iodide, thallium bromide, gallium arsenide, or silicon. In further embodiments, the semiconductor material may comprise Cd₍₁₋ₓ₎ Znₓ Te (where x is less than or equal to 0.5), a wide band gap ternary II-VI compound semiconductor with unique electronic properties. This type of semiconductor is useful in gamma-ray and X-ray detectors which are used as spectrometers that operate at room temperature for radiation detection, spectroscopy and medical imaging applications.

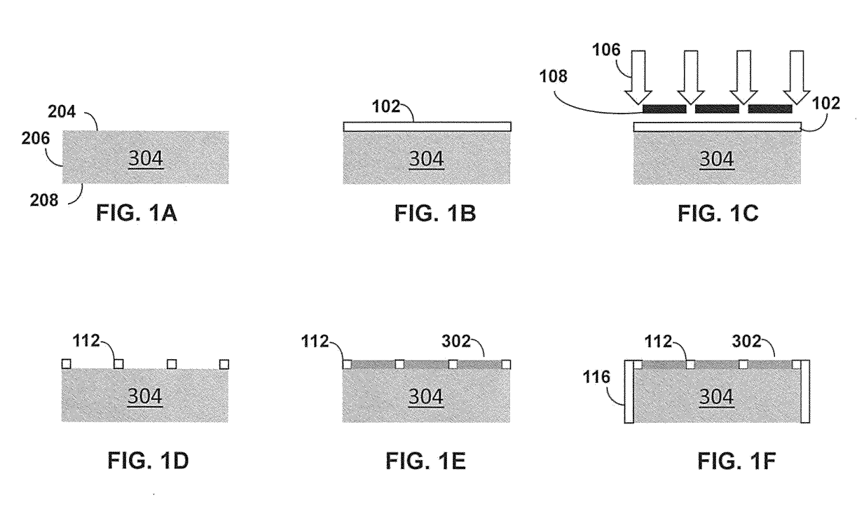

FIGS. 1A-F illustrate various stages of forming anode electrode pixels on a semiconductor substrate in an embodiment method of making a radiation detector. FIG. 1A is a side cross sectional view of a semiconductor substrate 304. A semiconductor substrate 304 may comprise any of the various semiconductors discussed above, such as CZT. The semiconductor substrate 304 may be shaped like a plate with a front major surface 208 and a rear major surface 204. The front major surface 208 and the rear major surface 204 may be substantially parallel. The semiconductor substrate 304 may also include side surfaces 206. The side surfaces 206 (or a single side surface for a plate having a circular or oval shape when viewed from the top) comprise plate edges and have a thickness that is at least 10 times smaller than the length and width of each major surface 204, 208. FIG. 1B is a cross sectional view with a first layer 102 of electrically insulating material applied over the rear major surface 204 of semiconductor substrate 304. While layer 102 may comprise any suitable insulating material, preferably layer 102 comprises a photosensitive, permanent insulating material, such as solder mask. FIG. 1C illustrates how the first solder mask layer 102 may be patterned by exposure to radiation 106. Radiation 106, such as ultraviolet radiation, may be applied through openings in a mask 108. Regions of the solder mask layer 102 that were not exposed to radiation may be removed leaving a configuration of pixel separation regions 112 such as that shown in FIG. 1D. In alternate embodiments, the regions of solder mask exposed to radiation may be removed leaving the unexposed regions as pixel separation regions 112. Thus, the solder mask layer 102 is patterned by photolithography. If a material other than photosensitive solder mask is used for layer 102, then it may be patterned by forming a photoresist layer above it, exposing the photoresist layer to radiation through the mask 108, removing exposed or unexposed photoresist regions (depending if positive or negative resist is used), and etching the layer 102 using the remaining photoresist regions as a mask. The remaining photoresist regions may then be removed by ashing or other suitable methods.

As shown in FIG. 1E, anode electrode pixels 302 may be formed on the rear major surface 204 between the pixel separation regions 112. The anode electrode pixels 302 may comprise a variety of conductive materials, such as gold. The anode electrode pixels 302 may be formed by any suitable process, such as electroless plating, sputtering, etc. Any excess material formed in the process (e.g., conductive material above the separation regions 112) may be removed by polishing or chemical mechanical polishing where the separation regions act as a polish stop. Side insulating layer 116, such as a side solder mask layer 116 or another suitable electrically insulating material may be formed over side surface(s) 206 of semiconductor substrate 304 as shown in FIG. 1F.

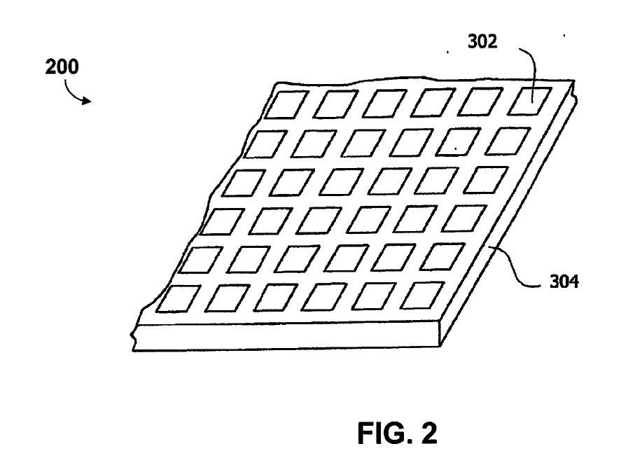

FIG. 2 illustrates a portion of a device 200 that may be formed by the steps shown in FIGS. 1A-F. Device 200 includes a semiconductor substrate 304 with an array of anode electrode pixels 302 on one side. As shown in FIG. 2, the anode electrode pixels 302 may be spread out evenly across the semiconductor substrate 304. The plurality of anode electrode pixels may be held at an electric potential when the device 200 is used as part of a radiation detector. Some of the anode electrode pixels 302 may be on the edge or corners of the array near the sides of the semiconductor substrate 304. These edge or corner pixels may perform less efficiently than the other anode electrode pixels 302 due to edge leakage current.

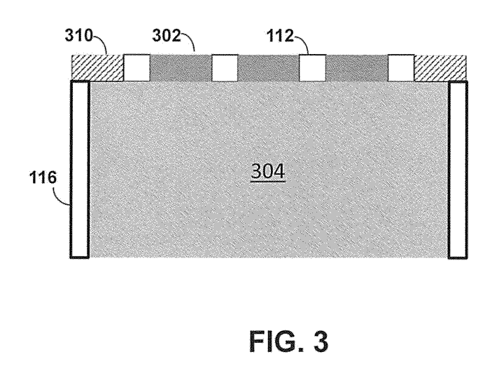

Further embodiments may include a guard ring 310. FIG. 3 illustrates a cross section of a device 300 similar to that shown in FIG. 1F but with a guard ring 310. Guard ring 310 may be formed over the rear major surface 204 of the semiconductor substrate 304. The guard ring 310 may be a pattern of conductive material (e.g., gold or another metal) formed around and/or toward an outer perimeter of the semiconductor substrate 310 and may be held at the same potential as the anode electrode pixels 302. However, in certain embodiments, the guard ring 310 is not used as part of a radiation detection channel like the anode pixels (i.e., no signal is detected from the guard ring). Instead, the guard ring 310 may be used to reduce edge leakage current and thereby improve peripheral pixel performance and compensate for degraded performance of edge pixels.

The guard ring 310 may be formed in the same step as forming the anode electrode pixels 302 by depositing a conductive material (e.g., gold) over the rear major surface 204 of the substrate 304 between and over the pixel separation regions 112 and polishing away a portion of the conductive material located above the pixel separation regions to leave the pixels 302 and guard ring 310 on the rear major surface of the substrate.

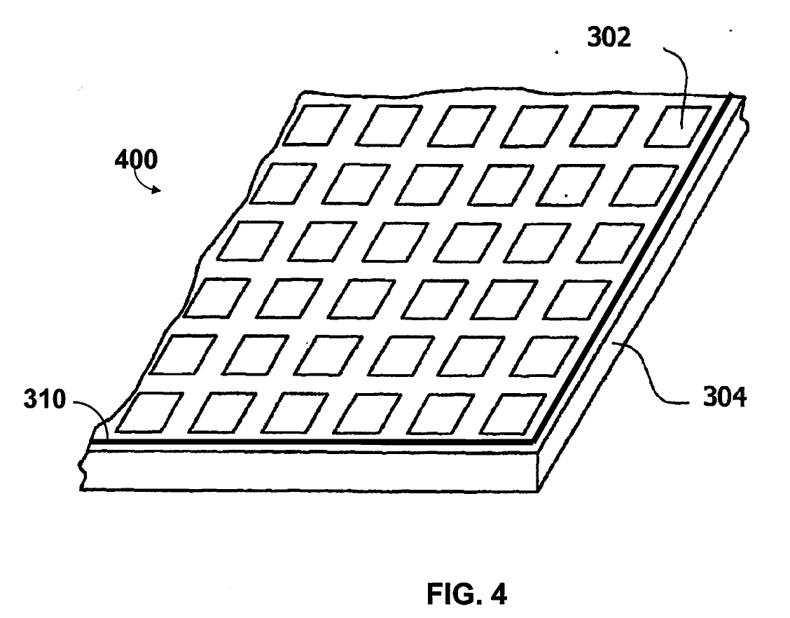

FIG. 4 illustrates a portion of a device 400 similar to the device 200 in FIG. 2 except that it includes a guard ring 310. The guard ring 310 may be located near the edges of a semiconductor substrate 304 and surround an array of anode electrode pixels 302.

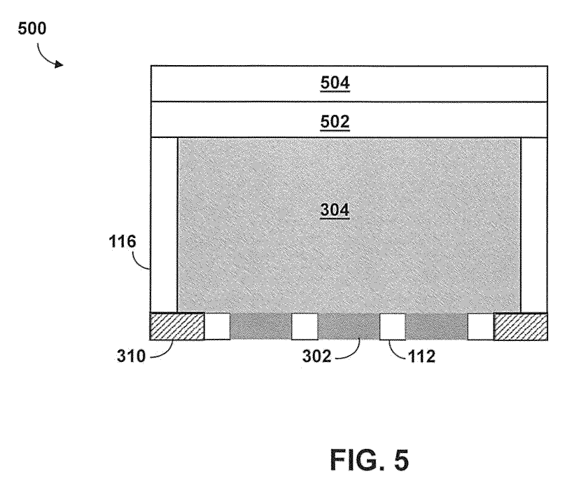

FIGS. 5-7 illustrate steps in a method of making an extended cathode according to an embodiment. The steps shown in FIGS. 5-7 may be carried out before or after the steps of making the anode pixels shown in FIGS. 1-4. FIG. 5 illustrates a cross section of a device 500 which may be a stage in an embodiment method of making a radiation detector. Device 500 may include a semiconductor substrate 304 with anode electrode pixels 302 formed on a rear major surface 204 (which points up in FIG. 5 rather than down as in FIGS. 1-4). It may also have a guard ring 310 and pixel separation regions 112 on the rear major surface 204, as well as side solder mask layer(s) 116 formed over side surface(s) 206, similar to the device in FIG. 3. Device 500 may also include cathode layers 502 and 504 over the front major surface 208 (pointing up in FIG. 5) of the semiconductor substrate 304. A first cathode layer 502 may formed directly on the front major surface 208. A second cathode layer 504 may be formed on top of the first cathode layer 502. The first cathode layer 502 may comprise indium. The second cathode layer 504 may comprise gold. Each cathode layer may be formed by any suitable method, such as electrolytic plating (i.e., electroplating). Alternatively, the layers 502, 504 may be formed by physical vapor deposition, such as sputtering.

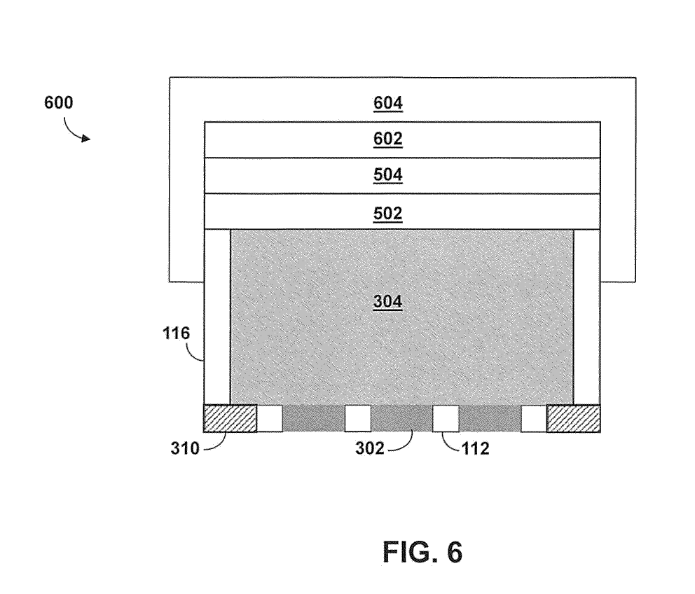

FIG. 6 illustrates a cross section of a device 600 at a later stage than the device 500 in the method of making the radiation detector. Device 600 is similar to device 500 but includes two additional layers. A layer 602 of photoresist or another sacrificial material (e.g., polymer or organic material) may be formed over the cathode layer 504. A layer 604 of conductive material may be formed over the photoresist layer 602 and may extend down the sides of device 600 such that conductive layer 604 contacts the edges of the cathode layers 502 and 504. The conductive layer 604 also extends over the upper portion(s) of the side solder mask layer(s) 116 located over the side surface(s) 206 of substrate 304. The conductive layer 604 may comprise gold and may be formed by any suitable method, such as sputtering, plating etc. Preferably, layer 604 is formed by physical vapor deposition, such as sputtering, such that it extends over the front and side surfaces of the substrate, while layers 502 and 504 are formed by plating, such as selective electroplating, such that they are located only over the front surface of the substrate exposed between the side solder mask layer(s) 116 on the side surface of the substrate.

The indium cathode layer 502 is protected with the photoresist layer 602 during sputtering of the extended gold cathode layer 604 to avoid possible indium cathode 502 and/or CZT substrate 304 crystal damage and weakening of the indium layer 502 contact with the CZT substrate 304 after sputter deposition. The reduction in damage improves (i.e., reduces) the device dark leakage current.

If desired, the lower portion of the solder mask layer(s) 116 located adjacent to the anode pixels may be masked with a removable masking material, such as masking tape or another suitable masking material to prevent deposition of layer 604 onto the lower portion(s) of the solder mask layer(s) 116. Layer 604 may extend down the top 10 to 60% of the side solder mask layer(s) 116 when measured from the top of layer(s) 116.

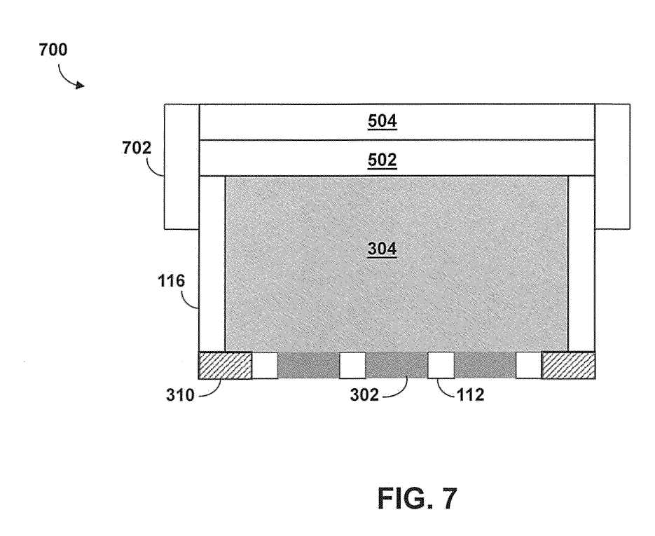

The photoresist layer 602 may be lifted off to expose the cathode layer 504 beneath. Lifting off of the photoresist layer 602 may also remove a top portion of the conductive layer 604 located over the photoresist layer 602. The lift off may results in the device 700 illustrated in FIG. 7. The side part(s) of the conductive layer 604 remain as an electrically conductive cathode extension 702 which may extend around the embodiment device 700. The cathode extension 702 may be in physical and electrical contact with the edge of the cathode layers 504 and 502 and thereby effectively extend the cathode over the side of the substrate 304. The extension 702 is located over the upper portion(s) of the side solder mask layer(s) 116.

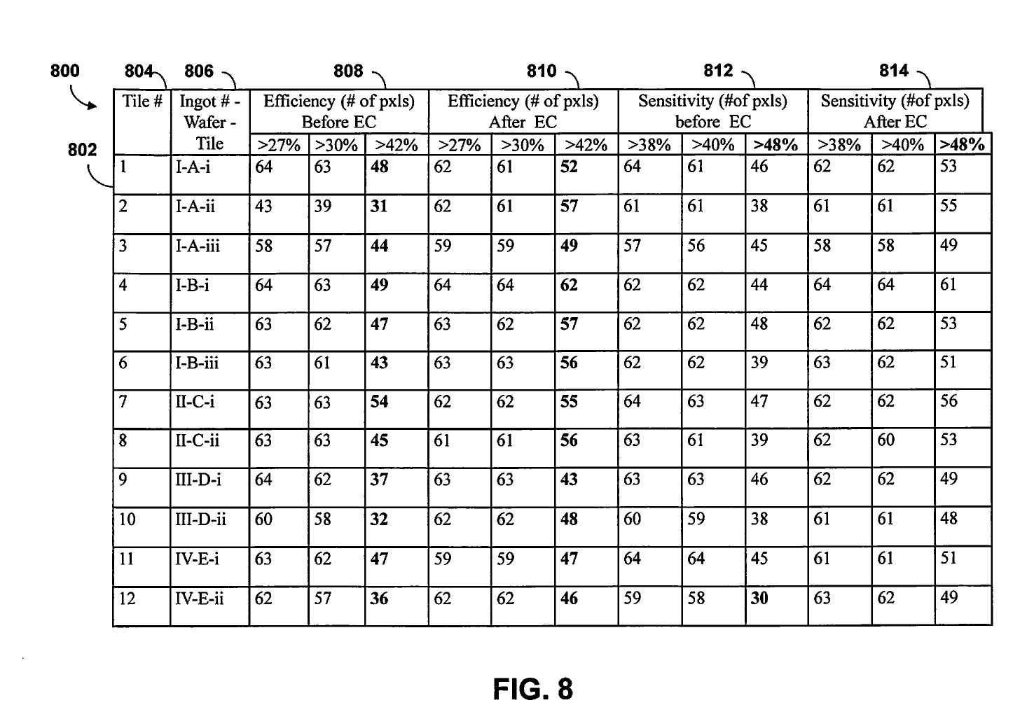

Extension of the cathode in embodiment radiation detectors may improve their performance. FIG. 8 illustrates experimental data demonstrating improved performance by embodiment radiation detectors with extended cathodes. Table 800 shows the gains in efficiency and sensitivity from extending cathodes of various detector tiles. Sensitivity may be defined as the ratio of the photopeak counts in the 13% window around the 122 keV photopeak divided by the total counts from 60 keV to 129 keV. Efficiency may be defined as the ratio of the photopeak counts in the 13% window around the 122 keV photopeak divided by the total 122 keV photons incident on the detector per pixel.

Column 804 includes an identification number for each tile tested. The test results of each tile are arranged in a row 802. Column 806 includes identification numbers based on the materials used to make each tile. The numbers include a first large Roman numeral identifying which ingot was used (i.e., four ingots numbered I to IV were used), a letter identifying which wafer the semiconductor substrate was sliced from (i.e., five wafers numbered A-E were used, where wafers A and B were both sliced from ingot I) and a final small Roman numeral to distinguish detector tiles made from the same ingot and wafer.

Embodiment detectors may include several configurations and variations in size and shape. For example, the detectors used to generate the test results in FIG. 8 included 64 pixels per tile. The inner pixels were 2.2 mm by 2.2 mm, the edge pixels were 2.2 by 2.02 mm, and the corner pixels were 2.02 mm by 2.02 mm. The distance between pixels was 260 μm. The tested tiles included guard rings with a thickness of 120 μm and no steering grid.

Column 808 of table 800 includes values of efficiency for each tile tested before extension of the cathode. Column 808 shows the data for the devices of the comparative examples without the extended cathode 702. Column 808 includes three subcolumns with different percentages. The values in these subcolumns represent the number of pixels on the tile that exceed the subcolumn's percent efficiency. For example, for tile 1, 48 pixels out of the total 64 pixels per tile exceeded 42% efficiency. Column 810 is organized the same as column 808 except that the values are for an embodiment detector tile with an extended cathode according to the exemplary embodiments. For example, for tile 1, 52 pixels of the total 64 pixels per tile exceeded 42% efficiency. Thus, the extended cathode appears to have boosted the number of pixels with efficiency over 42% from 48 to 52, assuming no other changes to the tiles.

In general, the present inventors were able to obtain tiles (i.e., substrates 304) with at least 85% of the total pixels, such as 86-96% of the total pixels having greater than 42 percent efficiency for a given tile (e.g., tiles 2 and 4-8 in FIG. 8) with an extended cathode 702. In contrast, for all tiles of the comparative examples, without the extended cathode, 84% or less of the pixels had an efficiency of above 42%.

Column 812 of table 800 is similar to column 808, but includes values for sensitivity rather than efficiency. Column 812 also differs from the column 808 in the percentage value of each subcolumn. Column 812 includes values for sensitivity of tiles without an extended cathode according to the comparative examples. Like columns 808 and 810, the values represent the number of pixels out of the 64 pixels per tile that exceed the percentage of each subcolumn. Column 814 includes values for sensitivity like column 812 for the same tiles but with an extended cathode according to the exemplary embodiments. For example, tile 1 had 46 pixels out of the total 64 pixels with greater than 48 percent sensitivity without an extended cathode as seen in column 812. Tile 1 had 53 pixels out of the total 64 pixels with greater than 48 percent sensitivity after an extended cathode was added. Thus, the extended cathode appears to have increased the number of pixels with greater than 48 percent sensitivity from 46 to 53.

In general, the present inventors were able to obtain tiles (i.e., substrates 304) with at least 76% of the total pixels, such as 77-95% of the total pixels having greater than 48 percent sensitivity for a given tile (e.g., tiles 2 and 4-8 in FIG. 8) with an extended cathode 702. In contrast, for all tiles without the extended cathode, 75% or less of the pixels had a sensitivity of above 48%.

The following improvement is achieved with the extended cathode 702 and the guard ring 310. On the average, 0.9% improvement is achieved on the mean full width half maximum (“FWHM”) of the peaks in the detector output spectra. On average, 17% improvement is achieved on the number of pixels with FWHM≦8%. On average, 4-5% improvement is observed on the of edge pixels efficiency. On average, 10% improvement was seen in the percentage of pixels exceeding the 42% efficiency criteria. On average, 10% improvement is seen in the percentage of pixels exceeding the 48% sensitivity criteria.

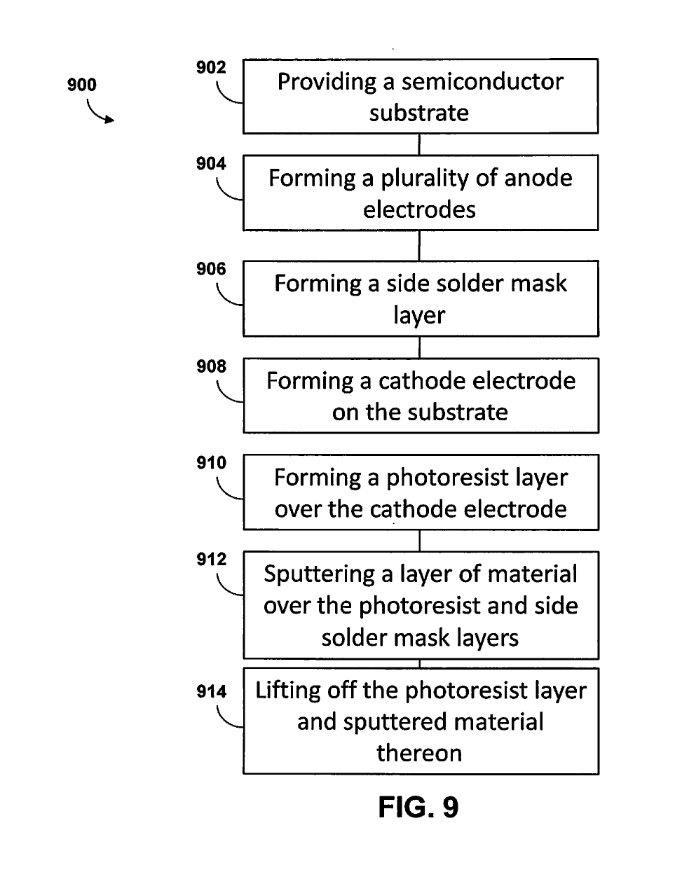

FIG. 9 illustrates a flow chart of an embodiment method 900 of producing radiation detectors 700. In step 902, a semiconductor substrate 304 may be provided. In step 904, a plurality of anode electrodes may be formed on the semiconductor substrate 304. These anode electrodes may be arranged in an array of pixels. The anode electrode pixels 302 may be formed on the rear major surface 204 of the semiconductor substrate 304 and face away from a radiation source in the embodiment radiation detector 700. Various conductive materials may be used to form the anode electrode pixels 302. For example, anode electrode pixels 302 may comprise Pt, Pd, In, Ni, Al, or Au.

Step 904 may comprise forming anodes by reverse lithography. Anode electrode pixels 302 may be formed by a series of steps. A layer 102 of solder mask may be formed over the rear major surface 204. The solder mask layer 102 may be patterned into pixel separation regions 112, such as by selectively applying radiation and removing portions of the solder mask. The anode electrode pixels 302 may be formed by any plating or vapor deposition method and located between the pixel separation regions 112. Alternatively, the pixels 302 may be formed over the substrate 304 first followed by forming the separation regions 112 between the pixels 302.

In step 906, a side insulating layer 116, such as a side solder mask layer 116 may be formed over the side surface(s) 206 of the semiconductor substrate 304. In step 908, a cathode electrode may be formed over the front major surface 208 of the semiconductor substrate 304. The cathode electrode may comprise two layers. A first cathode layer 502 may be formed directly over the front major surface 208 of the semiconductor substrate 304. This first layer 502 may comprise indium and be formed using any suitable method, including electrolytic plating. A second cathode layer 504 may be deposited over the first cathode layer 502. The second cathode layer 504 may comprise gold and may also be formed using any suitable method, including electrolytic plating.

In step 910, a photoresist layer 602 may be formed over the second cathode layer 504. In step 912, a layer 604 of material may be sputtered over the photoresist layer 602. The material may be any suitable conductive cathode material, such as gold. The conductive layer 604 may extend down the sides of the device and contact the edges of the first and second cathode layers 502 and 504, as well as covering the upper portion(s) of the side solder mask layer 116.

In step 914, the photoresist layer may be lifted off. A first portion of the conductive layer 604 over the cathode and over the front major surface of the substrate is removed by the lift off process. A second portion of the conductive layer 604 remains as the cathode extension. As noted above, step 904 may be performed before or after steps 908-914.

Further embodiment methods may also include steps for forming a guard ring 310 on the rear major surface 204. The guard ring 310 may comprise various conductive materials, such as gold. The guard ring may be formed during the same patterning step as the pixels 302.

The preceding description of the disclosed aspects is provided to enable any person skilled in the art to make or use the present invention. Various modifications to these aspects will be readily apparent to those skilled in the art, and the generic principles defined herein may be applied to other aspects without departing from the scope of the invention. Thus, the present invention is not intended to be limited to the aspects shown herein but is to be accorded the widest scope consistent with the principles and novel features disclosed herein.

What is claimed is:

1. A method of making a semiconductor radiation detector, comprising:
providing a semiconductor substrate comprising front and rear major surfaces and at least one side surface;
forming a plurality of anode electrodes over the rear major surface of the substrate;
forming a side insulating layer over the at least one side surface of the substrate;
forming a cathode electrode over the front major surface of the substrate;
forming a sacrificial layer over the cathode electrode;
forming a conductive material layer over the sacrificial layer and over at least a portion of the side insulating layer; and
lifting off the sacrificial layer to remove a first portion of the conductive material layer located over the cathode electrode while leaving a second portion of the conductive material layer over the side insulating layer such that the second portion of the conductive material layer contacts an edge of the cathode electrode.

2. The method of claim 1, wherein:
forming the cathode electrode comprises forming an indium layer on the front major surface of the substrate and forming a first gold layer on the indium layer;
forming the side insulating layer comprises forming a side solder mask layer;
forming the sacrificial layer comprises forming a photoresist sacrificial layer; and
forming the conductive material layer comprises sputtering a second gold layer.

3. The method of claim 2, wherein forming a plurality of anode electrodes over the rear major surface of the substrate comprises:
forming a rear solder mask layer over the rear major surface of the substrate;
patterning the rear solder mask layer into a plurality of pixel separation regions; and
forming anode electrode pixels over the rear major surface of the substrate, wherein each anode electrode pixel is formed between adjacent pixel separation regions.

4. The method of claim 3, further comprising forming a guard ring on the rear major surface of the substrate.

5. The method of claim 4, wherein forming the guard ring comprises forming the guard ring in the same step as forming the anode electrode pixels by depositing a conductive material over the rear major surface of the substrate between and over the pixel separation regions and polishing away portions of the conductive material located above the pixel separation regions.

6. The method of claim 5, wherein the anode electrode pixels and the guard ring comprise at least one material selected from the group consisting of Pt, Pd, In, Ni, Al, and Au.

7. The method of claim 6, wherein the substrate comprises single crystal CdTe or single crystal CZT.

8. The method of claim 3, wherein the step of patterning the rear solder mask layer into a plurality of pixel separation regions comprises exposing the rear solder mask layer to radiation through a mask and removing unexposed regions of the rear solder mask layer.

9. The method of claim 3, wherein the step of patterning the rear solder mask layer into a plurality of pixel separation regions comprises exposing the rear solder mask layer to radiation through a mask and removing exposed regions of the rear solder mask layer.

10. The method of claim 1, wherein at least 85 percent of total pixels on the substrate have greater than 42 percent efficiency, and at least 76 percent of the total pixels on the substrate have greater than 48 percent sensitivity.

11. A radiation detector, comprising:
a semiconductor substrate comprising front and rear major surfaces and at least one side surface;
a guard ring and a plurality of anode electrode pixels located over the rear surface of the semiconductor substrate, wherein each anode electrode pixel is formed between adjacent pixel separation regions;
a side insulating layer formed on the at least one side surface of the semiconductor substrate;
a cathode electrode located over the front major surface of the semiconductor substrate; and
an electrically conductive cathode extension formed over at least a portion of side insulating layer, wherein the cathode extension contacts an edge of the cathode electrode.

12. The device of claim 11, wherein:
the pixel separation regions comprise rear solder mask regions;
the cathode electrode comprises an indium layer on the front major surface of the substrate and a first gold layer on the indium layer;
the side insulating layer comprises a side solder mask layer; and
the cathode extension comprises a second gold layer different from the first gold layer.

13. The device of claim 12, wherein the anode electrode pixels and the guard ring comprise at least one material selected from the group consisting of Pt, Pd, In, Ni, Al, and Au.

14. The device of claim 13, wherein the substrate comprises single crystal CdTe or single crystal CZT.

15. The device of claim 11, wherein at least 85 percent of total pixels on the substrate have greater than 42 percent efficiency.

16. The device of claim 15, wherein at least 76 percent of the total pixels on the substrate have greater than 48 percent sensitivity.

17. A radiation detector, comprising:
a semiconductor substrate comprising front and rear major surfaces and at least one side surface;
a plurality of anode electrode pixels located over the rear surface of the semiconductor substrate, wherein each anode electrode pixel is formed between adjacent pixel separation regions;
a side insulating layer formed on the at least one side surface of the semiconductor substrate;
a cathode electrode located over the front major surface of the semiconductor substrate; and
an electrically conductive cathode extension formed over at least a portion of side insulating layer, wherein the cathode extension contacts an edge of the cathode electrode;
wherein at least 85 percent of total pixels on the substrate have greater than 42 percent efficiency.

18. The device of claim 17, wherein:
the pixel separation regions comprise rear solder mask regions;
the cathode electrode comprises an indium layer on the front major surface of the substrate and a first gold layer on the indium layer;
the side insulating layer comprises a side solder mask layer; and
the cathode extension comprises a second gold layer different from the first gold layer.

19. The device of claim 17, wherein the anode electrode pixels and the guard ring comprise at least one material selected from the group consisting of Pt, Pd, In, Ni, Al, and Au, and the substrate comprises single crystal CdTe or single crystal CZT.

20. The device of claim 17, wherein at least 76 percent of the total pixels on the substrate have greater than 48 percent sensitivity.
